(19) United States
(12) Patent Application Publication
(10) Pub. No.: US 2024/0204079 A1
(43) Pub. Date: Jun. 20, 2024

(54) SELF-ALIGNED GATE METAL WITH TOP-DIELECTRIC ISOLATION

(71) Applicant: INTERNATIONAL BUSINESS MACHINES CORPORATION, ARMONK, NY (US)

(72) Inventors: Andrew Gaul, Halfmoon, NY (US); Julien Frougier, Albany, NY (US); Ruilong Xie, Niskayuna, NY (US); Andrew M. Greene, Slingerlands, NY (US)

(21) Appl. No.: 18/067,710

(22) Filed: Dec. 17, 2022

(51) Int. Cl. H01L 29/66; H01L 27/092; H01L 29/06; H01L 29/423; H01L 29/775

(52) U.S. Cl. CPC H01L 29/66439; H01L 27/092; H01L 29/0673; H01L 29/42392; H01L 29/775

(57) ABSTRACT

A semiconductor device includes a substrate and a stack of nanosheets supported by the substrate. A plurality of semiconductor channels in the stack of nanosheets includes a top channel. A gate body is coupled to the top channel. The gate body includes a layer of metal positioned on top of the top channel. A spacer body includes a top dielectric layer positioned on top of the layer of metal. A thickness of the layer of metal above the top channel is based on a distance from a bottom surface of the top dielectric layer to a top surface of the top channel.

### BACKGROUND

### Technical Field

The present disclosure generally relates to electrical devices, and more particularly, to a self-aligned gate metal with top-dielectric isolation.

### Description of the Related Art

In a nanosheet stacked transistor device, there are commonly metal gates surrounding the channels. The gate metal commonly rises above the top channel to an arbitrary height. The height level of the gate is commonly defined by a reactive-ion etching process. A self-aligned cap may sometimes be formed on top of the gate.

The metal gate height in a transistor device generally includes work function metal films. In the often complex structure of work function metal films, there can be a challenge in controlling the metal gate height from wafer to wafter resulting in variations between devices. Since in nanosheet style transistors, there is generally some gate metal above the top channel, to ensure that gate metal is present after planarization of the top of the device, excess gate metal may be applied. However, the metal gate height can directly affect performance of the device. For example, as the gate metal height increases, the parasitic capacitance between metal gates and adjacent conductors increases. An approximate one percent increase in AC performance degradation can be seen for every nanometer of gate metal that is above the top of a fin. So, any excess metal deposited above the top channel sacrifices some performance available to the device.

Variation in metal gate height may also cause variations in threshold voltages between devices. As may be understood, being able to control the threshold voltage is significant in controlling the ON/OFF states of a transistor device. As such, controlling the gate height can be helpful in producing consistently performing devices.

Variation in metal gate height may also contribute to yield degradation. Metal gates that rise too high above the fin can form short circuits with nearby metal structures.

### SUMMARY

In general, embodiments provide a semiconductor device and method of manufacture that aligns the gate metal height above the top channel of a transistor uniformly across different transistors. A dielectric layer is positioned above the top layer of metal in the gate above the top channel. As will be appreciated, the dielectric layer protects the underlying gate metal and top channel from inadvertent damage from etching during the manufacture process. Moreover, the thickness of the gate metal above the top channel can be controlled because the dielectric layer provides a buffer defining the threshold level for etching back materials on the top surface of the device. By controlling the thickness (or height) of the gate metal, negative characteristics including parasitic capacitance, asymmetry in layers, and inconsistent threshold voltages between transistor elements can be eliminated.

According to an embodiment of the present disclosure, a semiconductor chip device is provided. The semiconductor device includes a substrate and a stack of nanosheets supported by the substrate. A plurality of semiconductor channels in the stack of nanosheets includes a top channel. A gate body is coupled to the top channel. The gate body includes a layer of metal positioned on top of the top channel. A spacer body includes a top dielectric layer positioned on top of the layer of metal. A thickness of the layer of metal above the top channel is based on a distance from a bottom surface of the top dielectric layer to a top surface of the top channel.

In an embodiment, a distance between the top channel and an underlying semiconductor channel is spaced by the distance from the bottom surface of the top dielectric layer to the top surface of the top channel. The feature in this embodiment provides uniformity in the layers under the top gate metal. Asymmetry of top versus middle/bottom nanosheets occurs due to the top nanosheet being exposed throughout replacement metal gates processes that do not include the top dielectric layer of the subject disclosure. The top dielectric layer protects both the top metal gate layers and underlying gate layers so that performance down the stack of layers is consistent in a transistor.

According to an embodiment of the present disclosure, a semiconductor chip device is provided. The semiconductor device includes a substrate and a first fin field effect transistor (FET) on top of the substrate. A first stack of nanosheets is in the first fin FET. A first top semiconductor channel is in the first stack of nanosheets. A first bottom semiconductor channel is in the first stack of nanosheets. A second fin FET is on top of the substrate. A second stack of nanosheets is in the second fin FET. A second top semiconductor channel is in the second stack of nanosheets. A second bottom semiconductor channel is in the second stack of nanosheets. A gate body is coupled to the first top semiconductor channel, the second top semiconductor channel, the first bottom semiconductor channel, and the second bottom semiconductor channel. The gate body includes a layer of metal positioned on top of the first top semiconductor channel and on top of the second top semiconductor channel. A spacer body includes a top dielectric layer positioned on top of the layer of metal. A thickness of the layer of metal above the first top semiconductor channel is based on a distance from a bottom surface of the top dielectric layer to a top surface of either the first top semiconductor channel or the second top semiconductor channel.

In an embodiment, which may be combined with the preceding embodiments, the thickness of the layer of metal is uniform across the first fin FET and the second fin FET. As may be appreciated, consistency in metal gate height across transistors provides consistency in the expected or designed performance of devices. The top dielectric layer allows the metal gate height across transistors to be controlled which allows designers to confidently engineer targeted performance output for each transistor.

According to an embodiment of the present disclosure, a method of manufacturing a semiconductor device is provided. The method includes forming a stack of nanosheets on a substrate. The stack of nanosheets includes at least a first semiconductor channel and a second semiconductor channel, and at least a first sacrificial suspension layer on top of the first semiconductor channel, a second sacrificial suspension layer between the first semiconductor channel and the second semiconductor channel, and a third sacrificial suspension layer under the second semiconductor channel. A dielectric dummy layer is formed on top of the first sacrificial suspension layer. The dielectric dummy layer is removed to define an empty area on top of the first sacrificial suspension layer. A spacer dielectric is deposited into at least the empty area on top of the first sacrificial suspension layer. A fin field effect transistor (FET) is formed from the stack of nanosheets. At least some of the spacer dielectric is positioned on top of the fin FET. A source and a drain are coupled to the fin FET. The first, second, and third sacrificial suspension layers are removed. A gate metal is deposited in areas including, above the first semiconductor channel, in between the first semiconductor channel and the second semiconductor channel, and under the second semiconductor channel. A thickness of the gate metal positioned on top of the first semiconductor channel is pre-defined.

In an embodiment, which may be combined with the preceding embodiments, the method includes planarizing a top surface of the fin FET defined by a level into the layer of the spacer dielectric that material was removed. Previous conventional devices had inconsistent metal gate heights which made it difficult to control the planarity of the top surface. By controlling the metal gate height no self-aligning cap is needed. A direct gate metal polish becomes available and the device can be used for example, in advanced node applications.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1A-1C are cross-sectional views of a transistor with a self-aligned metal gate consistent with embodiments of the present disclosure.

FIG. 2 is a legend showing axes of from a top view perspective for the views in FIGS. 3A, 3B, 3C—21A, 21B, and 22C, consistent with embodiments of the present disclosure.

FIGS. 3A-3C show views of an initial starting formation for a process of fabricating a semiconductor device with a self-aligned metal gate, according to embodiments.

FIGS. 4A-4C show views of depositing a hard mask and patterning, according to an embodiment.

FIGS. 5A-5C show views of releasing sacrificial layers, according to an embodiment.

FIGS. 6A-6C show views of depositing a continuous spacer, according to an embodiment.

FIGS. 7A-7C show views of etching the spacer and a fin recess, according to an embodiment.

FIGS. 8A-8C show views of indenting dummy gate areas, according to an embodiment.

FIGS. 9A-9C show views of interlayer spacer deposition and etch back, according to an embodiment.

FIGS. 10A-10C show views of an epitaxial source-drain formation, according to an embodiment.

FIGS. 11A-11C show views of a liner deposition, interlayer dielectric fill, chemical mechanical planarization, and hard mask reduction process, according to an embodiment.

FIGS. 12A-12C show views of a hard mask removal and polysilicon or amorphous silicon etch, according to an embodiment.

FIGS. 13A-13C show views of dielectric etching, according to an embodiment.

FIGS. 14A-14C show views removing dummy nanosheet channel layers, according to an embodiment.

FIGS. 15A-15C show views depositing interlayer High-K gate dielectric film, according to an embodiment.

FIGS. 16A-16C show views of depositing work function metal films and patterning, according to an embodiment.

FIGS. 17A-17C show views of planarizing to the TDI level, according to an embodiment.

FIGS. 18A-18C show views depositing a middle of line interlayer dielectric layer, according to an embodiment.

FIGS. 19A-19C show views etching the interlayer dielectric for a metal contact to gate opening, according to an embodiment.

FIGS. 20A-20C show views etching the interlayer dielectric for a metal contact source-drain opening, according to an embodiment.

FIGS. 21A-21C show views forming the metal contacts for gate and source-drain, according to an embodiment.

FIGS. 22A-22C show views forming the metal contacts for gate and source-drain on a nanosheet FET with a top dielectric level but no bottom dielectric level, consistent with embodiments of the present disclosure.

FIGS. 23A-23C show views of depositing work function metal films and patterning, according to an embodiment.

FIGS. 24A-24C show views of recessing a metal gate, according to an embodiment.

FIGS. 25A-25C show views of depositing a self-aligned cap over the top dielectric, according to an embodiment.

FIGS. 26A-26C show views depositing a middle of line interlayer dielectric layer over the self-aligned cap, according to an embodiment.

FIGS. 27A-27C show views etching the interlayer dielectric and self-aligned cap for a metal contact to gate opening, according to an embodiment.

FIGS. 28A-28C show views etching the interlayer dielectric and self-aligned cap for a metal contact to source-drain opening, according to an embodiment.

FIGS. 29A-29C show views forming the metal contacts for gate and source-drain on a nanosheet FET with a top dielectric level but no bottom dielectric level, consistent with embodiments of the present disclosure.

FIGS. 30A-30C show views forming the metal contacts for gate and source-drain on a nanosheet FET with a top dielectric level but no bottom dielectric level, consistent with embodiments of the present disclosure.

### DETAILED DESCRIPTION

### Overview

In conventional stacked transistor devices, transistor structures generally struggle with consistency in the height of a metal gate above the top channel. In general, embodiments in the disclosure provide a semiconductor device that provides self-aligning metal gates whose height over the top channel is controllable and consistent between transistors. As will be appreciated, by self-aligning the metal gate to a reduced height, the device provides improvement in AC performance without having to use substantial chemical mechanical polishing (or planarization) development or advanced process control.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Nanosheets are typically able to maintain DC performance due to an adequate effective gate width, but AC performance is challenging because of the relatively large parasitic capacitance between the source/drain contact and gate. Cell height scaling difficulties are another issue, due to gate stack patterning challenges associated with tall nanosheet stacks. Tall nanosheet stacks are desirable, however, because they provide the same effective length at a smaller footprint, directly enabling area scaling.

In general, a dielectric spacer layer is formed over metal above the top channel of transistors so that the thickness of gate metal above the top channel (and below the spacer) can be controlled. The spacer protects the underlying gate metal from inadvertent removal of gate material. In addition, the spacer provides a buffer from the gate metal so that the thickness of the gate metal may be formed to maximize performance (for example, by avoiding unnecessary metal that contributes to parasitic capacitance).

In other aspects that should be appreciated, the processes disclosed provide the capability to re-balance the ratio of dummy gate height to nanosheet stack height. More sheets may be included in the device structure while reducing defectivity from having a tall dummy gate (for example, due to issues stemming from tall aspect ratios). In addition, variations in threshold voltage for channels are reduced due to the self-aligned metal height. Asymmetry between top nanosheet layers versus middle/bottom nanosheets is reduced due to protection of the top sheet by a top dielectric isolation layer throughout the replacement metal gate process.

In conventional nanosheet device processes, strict chemical mechanical planarization control is used to define the final gate metal height. The top nanosheet can experience degradation due to exposure to reactive ion etching throughout processing. Thus, the top channel may have some electrical asymmetry with the lower channels because of differences that occur from exposure to the etch processing of the top surface. The subject methods do not require strict chemical mechanical planarization (or polishing) control to define the final gate metal height, improving on the current industry standard. As will be further appreciated, a direct gate metal polish becomes available, which is good for future integrations of other device features.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Example Device Structure

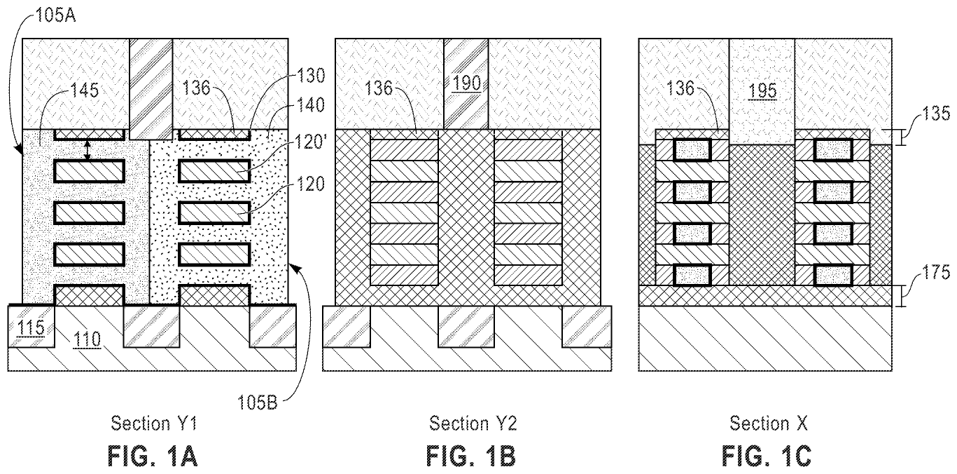

Referring now to FIGS. 1A-1C, a cross-sectional view of a semiconductor device 100 (referred to generally as the “device 100”) is shown, consistent with embodiments of the disclosure. The device 100 includes a height of the metal gate above a top channel 120′ that will be substantially uniform across multiple instances of the device 100. The “top channel” in this disclosure refers to the semiconductor channel 120 layer highest in the stack of nanosheets. The height of the gate metal above the top channel 120′ may be controlled by positioning a top dielectric isolation (TDI) layer 135 at a pre-defined distance above the top channel 120′. FIG. 1A shows arrows representing the controlled thickness of metal gate height above the top channel 120′. “Controlled” as used herein means that the thickness of material (i.e., the height of the gate metal) is predetermined and does not change during processing once deposited. The TDI layer 135 protects the top nanosheet defining the top channel 120′ from inadvertent material loss during planarization and etching processes from the top side of the device. As planarization occurs, the TDI layer 135 may be of enough thickness that the gate metal above the top channel 120′ will remain untouched.

As will be appreciated, the distance between the top surface of the top channel 120′ and the bottom surface of the TDI layer 135 can be reproduced consistently between instances of fabrication because the TDI layer 135 provides a buffer above the gate metal. The distance between the top channel 120′ and an underlying semiconductor channel 120 may be spaced by (or based on) the same distance from the bottom surface of the TDI layer 135 to the top surface of the top channel 120′.

In an embodiment, a substrate 110 supports one or more transistor devices. The substrate 110 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the present disclosure, the substrate 110 can include a buried oxide layer (not shown) in a silicon-on-insulator (SOI) configuration. The buried oxide layer can be made of any suitable dielectric material, such as, for example, a silicon oxide. In some embodiments of the invention, the buried oxide layer is formed to a thickness of about 10-200 nm, although other thicknesses are within the contemplated scope of the invention. In some embodiments of the present disclosure, the semiconductor structure of FIGS. 1A to 1C can also be formed without the buried oxide layer. In that case, an STI (shallow trench isolation) can be formed to isolate device from device.

For example, in the embodiment shown, two transistors (105A and 105B) are shown on the substrate 110. Isolation trench sections 115 isolate adjacent transistors 105A and 105B from each other at the substrate 110 level. The transistors 105A and 105B include a plurality of stacked nanosheet layers that alternate between semiconductor channels 120 and surrounding gate metal in work function metal (WFM) films 140 and 145. The left side transistor gate and the right side transistor gate may be the same metal or different metal. The transistors 105A and 105B share a top gate contact 190 that is electrically connected to respective gates in WFM films 140 and 145. A source to drain contact 195 may be electrically connected to the source/drain area of one transistor. (See FIG. 1C). The semiconductor channels 120 may be surrounded by an oxide layer 130 separating the semiconductor material from the gate metal. A spacer body 136 may continuously surround the stacks of nanosheets so that spacer material extends from the top surface of the device 100 down to the substrate 110 (See FIG. 1B). The spacer body 136 can be made of any suitable dielectric material, such as, for example, a low-k dielectric, nitrides, silicon nitride, silicon oxide, SiON, SiC, SiOCN, and SiBCN. Some embodiments may include the oxide layer 130 in areas separating the spacer body 136 from the surrounding gate metal in WFM films 140 or 145 (See FIG. 1A). In some embodiments, the spacer body 136 provides a bottom dielectric isolation (BDI) layer 175 between the substrate 110 and the bottom most semiconductor channel 120.

### Example Methodology of Manufacture

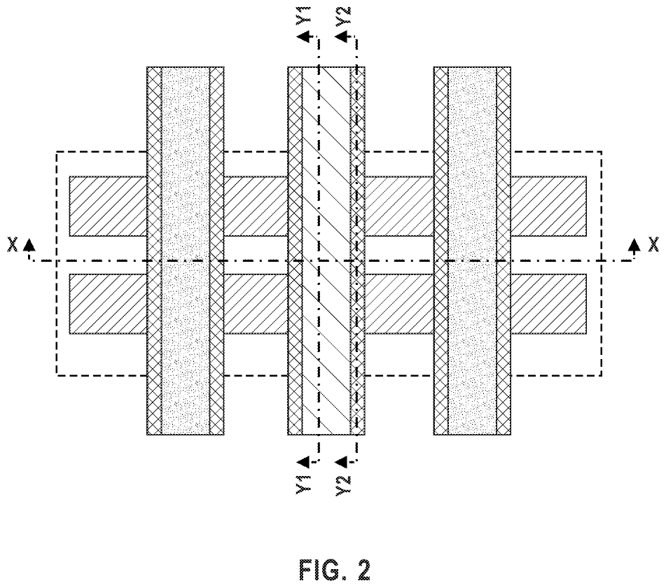

In the following, a process describes a general method of forming a semiconductor device 100 that has a self-aligned gate metal height. FIG. 2 shows a legend providing the various views of the semiconductor device during the fabrication process. In general, the legend is a top view of the device formation process after spacer deposition and pull down. Axis “X” is from an end view perspective between two stacks of nanosheets representing two transistor fins. Axis “Y1” is a cross-section from a side perspective inside the transistor layer. Axis “Y2” is a cross-section from a side perspective inside the spacer layer.

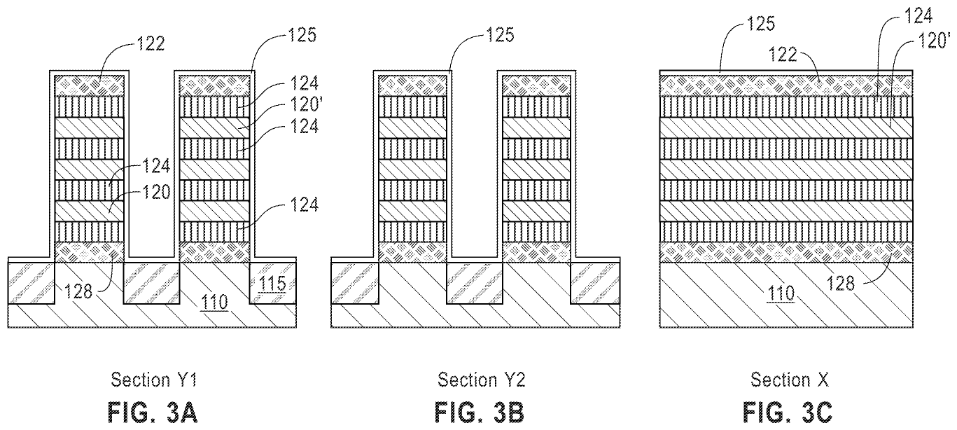

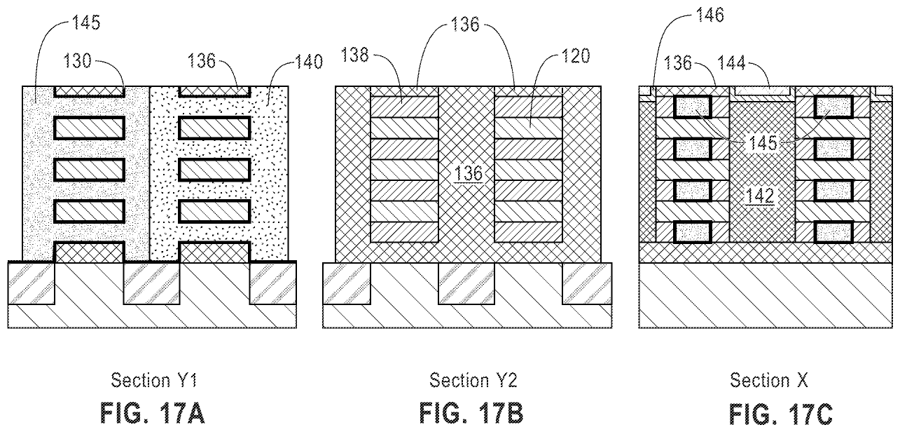

Reference is now made beginning at FIGS. 3A-3C to describe, by illustration, a method for manufacturing a semiconductor device 100 with controlled height of the gate metal above the top channel. FIGS. 3A-30D show a fabrication process including additive and subtractive processes to form some circuit elements in the end device. Reference back to FIGS. 1A-1C may be needed at times to identify structures not present in a step of the process being illustrated. The additive and subtractive processes involved (for example, masking, depositing, etching, lithography, etc.,) may be known to those of skill in the art and will not necessarily be identified in each act shown. The fabrication of the devices described herein can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, a device can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit. In some figures, some reference numerals for elements not being affected by a step may not be repeated.

Referring now to FIGS. 3A-3C, the process is shown from an initial starting point that includes two adjacent stacks of nanosheets formed on a substrate 110, which form the framework for respective fin FETs that will be produced by the end of the process. Those of ordinary skill in the art will understand the process to arrive at this initial structure without explanation of the formation of nanosheets on the substrate 110. The fin stack includes two or more layers of silicon semiconductor channels 120. The fin stack includes at least one placeholder layer, for example, a sacrificial suspension layer 124 above and below the top channel 120′. Below the top channel 120′, a sacrificial suspension layer 124 may be positioned between any additional silicon semiconductor channels 120. The area of the sacrificial suspension layer 124 above the top channel 120′ will be used to access the top channel 120′ later in the process.

In various embodiments, the sacrificial suspension layers 124 can be silicon or silicon germanium layers, depending on the material of the semiconductor layers to meet etch selectivity requirements. For example, in embodiments where the semiconductor layers 120 are silicon nanosheets, the sacrificial layers 124 can be silicon germanium layers. In embodiments where the semiconductor layers 120 are silicon germanium nanosheets, the sacrificial suspension layers 124 can be silicon germanium layers having a germanium concentration that is greater than the germanium concentration in the semiconductor layers 120. For example, if the semiconductor layers 120 are silicon germanium having a germanium concentration of 5 percent (sometimes referred to as SiGe5), the sacrificial suspension layers 124 can be silicon germanium layers having a germanium concentration of about 25 (SiGe25), although other germanium concentrations are within the contemplated scope of the present disclosure. In some embodiments of the present disclosure, the sacrificial layers 124 have a thickness of about 8 nm to about 15 nm (e.g., 10 nm), although other thicknesses are within the contemplated scope of the present disclosure.

The fin stack may include another sacrificial suspension layer 122 above the sacrificial suspension layer 124 that is on top of the top channel 120′. The area of the sacrificial suspension layer 122 will be used to deposit the spacer body 136 material that will form the TDI layer 135. The sacrificial suspension layer 122 may be formed from a silicon germanium mix (with a Ge % comprising 60% of the mix). The sacrificial suspension layers 124 may be formed from a silicon germanium mix (with a Ge % comprising 25% of the mix). For embodiments that will include a bottom dielectric isolation (BDI) layer 175, a bottom sacrificial suspension layer 122 may be included above the substrate 110 and below a sacrificial suspension layer 124. An oxide layer 125 may be deposited on top of and on the sides of the silicon semiconductor channels 120, sacrificial suspension layer(s) 122, sacrificial suspension layers 124, and the exposed areas of the isolation trench sections 115.

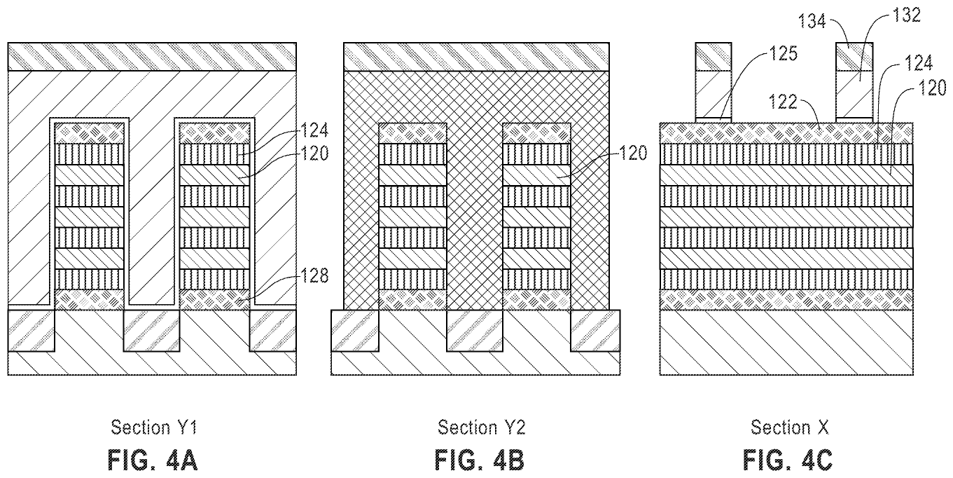

FIGS. 4A-4C show deposition of dummy gate layer 132 (using for example, an amorphous silicon or poly silicon) around the fin stacks. A hard mask 134 may be applied to the dummy gate layer 132 to perform PC patterning (using for example, an RIE process). The dummy gate layer 132 can serve as a placeholder and permit the placement of the source and drain regions of the device. In one embodiment, following formation of the source and drain regions, the dummy gate can be removed and replaced with a replacement gate stack. Thus, potential damage to the replacement gate stack (e.g., from processing conditions such as dopant implant and/or activation anneals) can be avoided since the gate stack is not formed until the end of the process.

As shown in FIG. 4C, at least one dummy gate 132 is formed over a portion of each of the nanowire stacks that will serve as a channel region of the device. The dummy gate 132 can be formed by blanket depositing a dummy gate material onto, and in between, the nanowire stacks and then patterning the dummy gate material into one or more individual dummy gates 132. Suitable dummy gate materials include, but are not limited to, poly-silicon (or poly-Si). As highlighted above, with the dummy gate 132 in place, the source and drain regions of the device can then be formed.

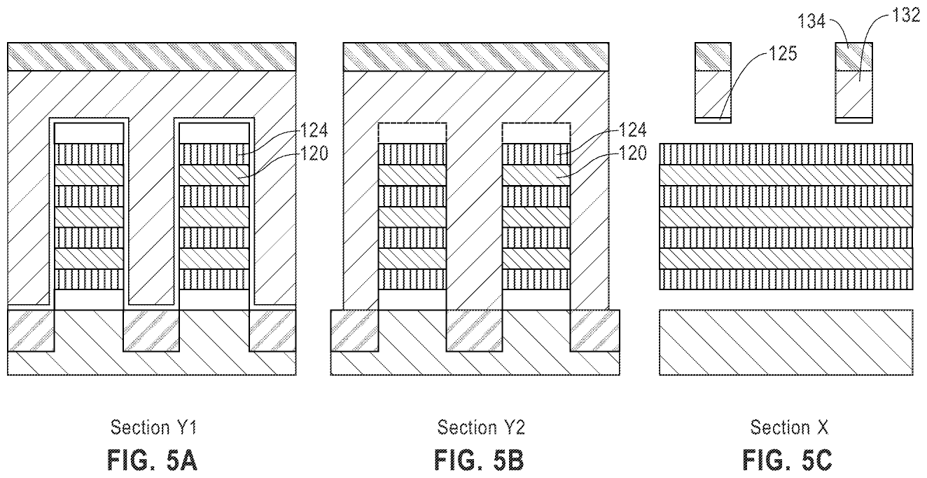

FIGS. 5A-5C show release (removing) of the top and bottom sacrificial suspension layers 122. In one embodiment, since the top and bottom sacrificial suspension layers 122 use the same material, both layers may be removed during the same process.

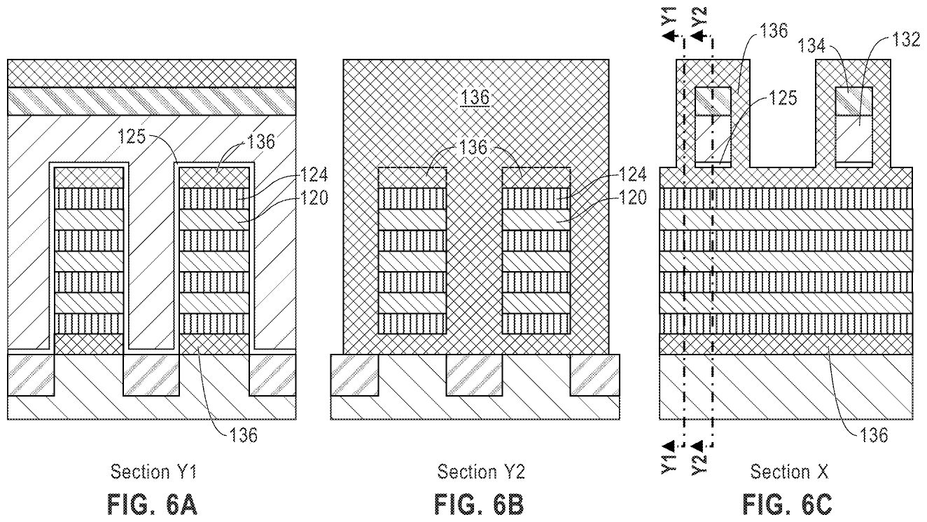

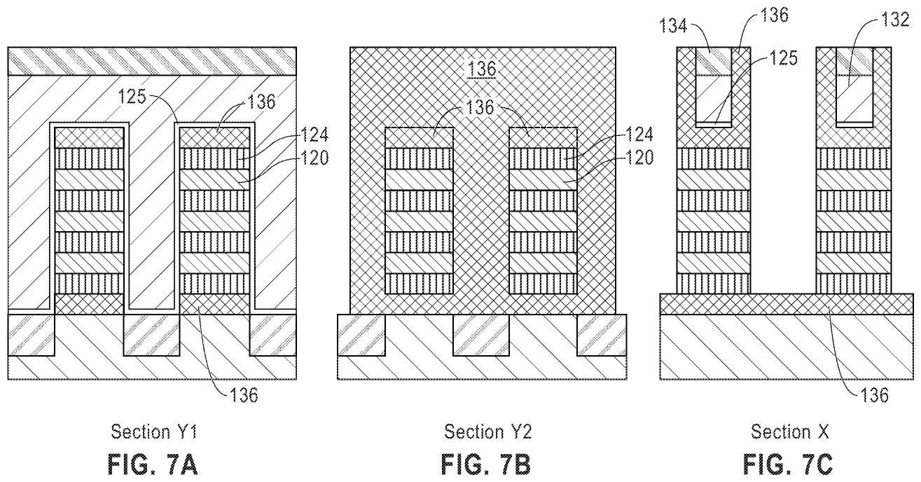

FIGS. 6A-6C show deposition of the spacer body 136 into the areas patterned out by the hard mask 134 and spaces that remain after removal of the sacrificial suspension layer(s) 122. As can be seen from the various views, the spacer body 136 may be formed as a single continuous layer that surrounds the eventual gate and channel areas. The continuous spacer body 136 protects the area around the fin stacks from possible gate to source/drain short circuits. FIGS. 7A-7B show etching of the spacer body 136 and recessing in between the fin stacks. In some embodiments, the recessing may be performed down to the BDI layer 175 of the spacer body 136.

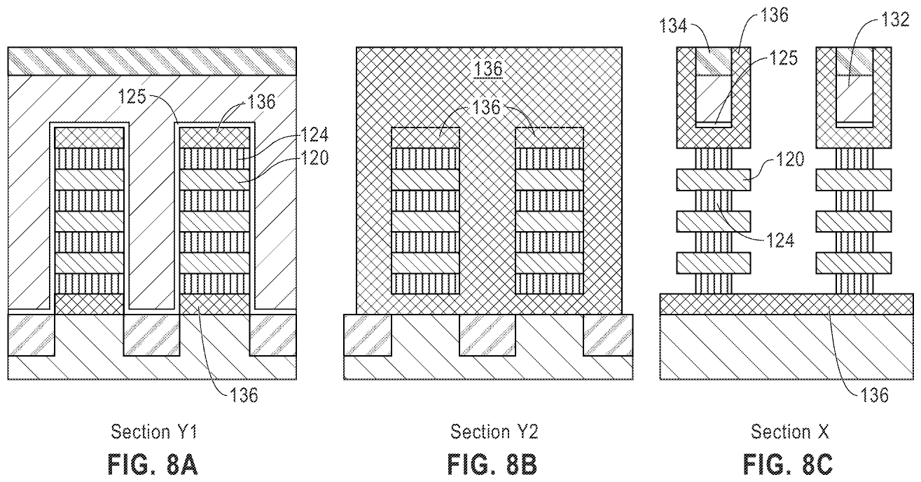

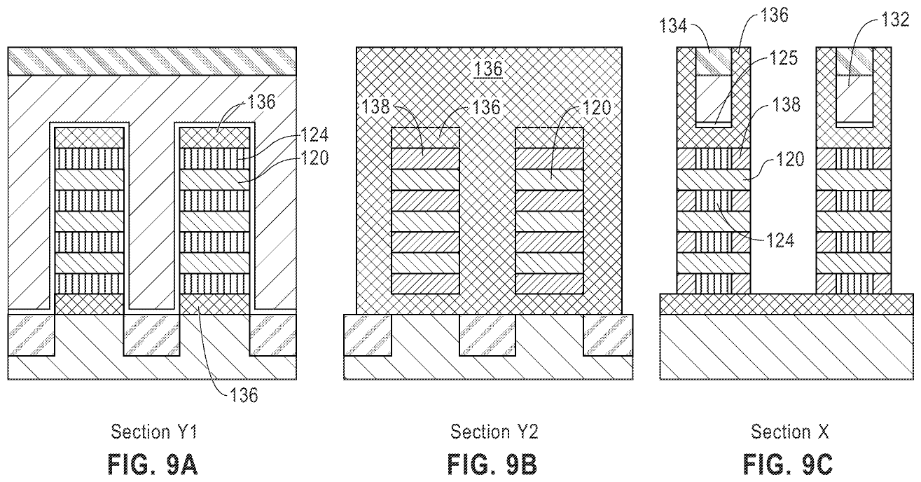

FIGS. 8A-8C show the formation after identing inward of some of the inter-spacer portions of the sacrificial suspension layers 124. FIGS. 9A-9C show the formation after depositing inter-spacer dielectric material 138 into the recesses and cavities formed from the previous process of identing. The formation shows the results of etching back excess spacer material 138 until the spacer material 138 is aligned with the boundaries of the semiconductor channels 120 (as shown in FIG. 9C).

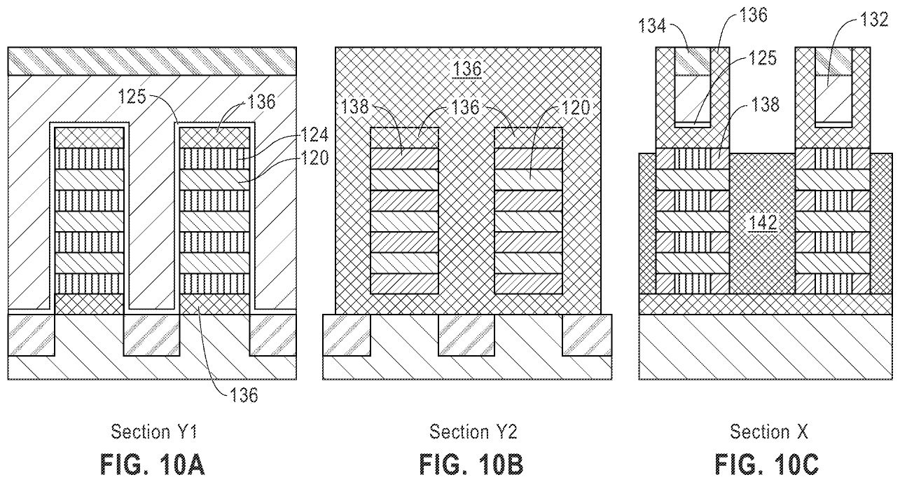

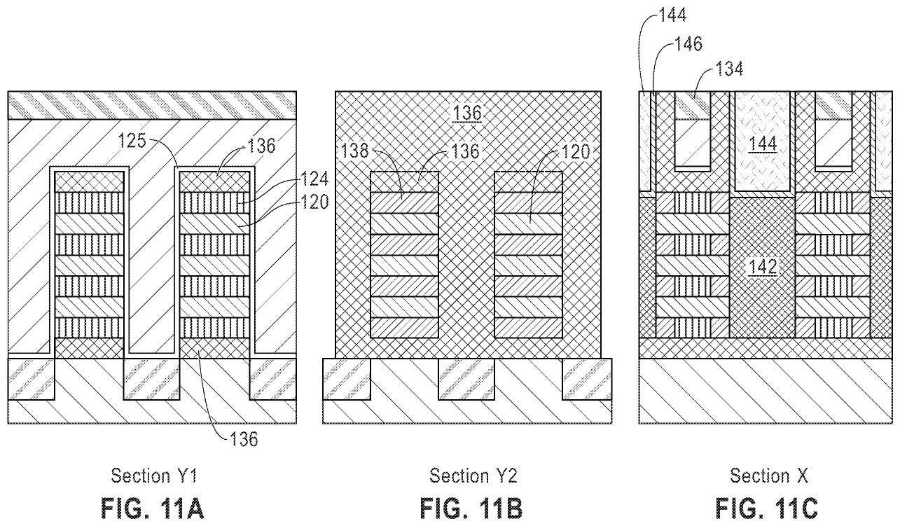

FIGS. 10A-10C show growth of the source-drain epitaxial layer 142 off the ends of the nanosheet layers. FIGS. 11A-11C show deposition of a Poly-open chemical mechanical polishing (POC) liner 146 over the epitaxial layer 142 and on the PC sidewalls. In addition, an interlayer dielectric (ILD) fill 144 may be applied to the open areas above and around the POC liner 146. The formation shows the post process of planarization on the ILD fill 144 and POC liner 146.

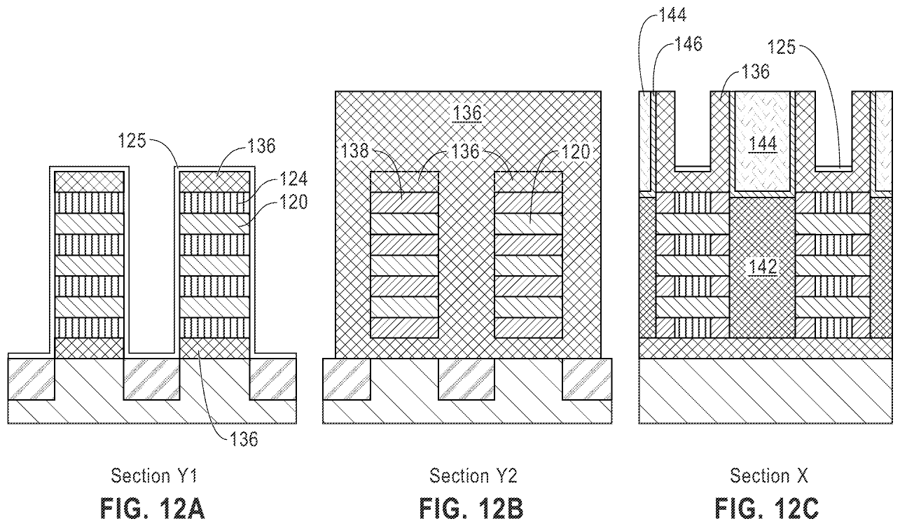

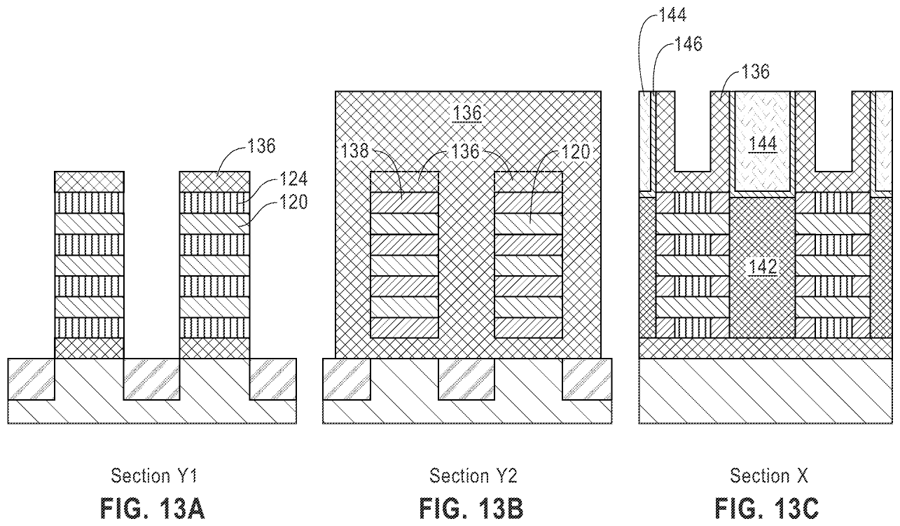

FIGS. 12A-12C show the formation after removal of the hard mask 134 and removal of the dummy gate layer 132. FIGS. 13A-13C show the formation after removal (etching) of the oxide layer 125.

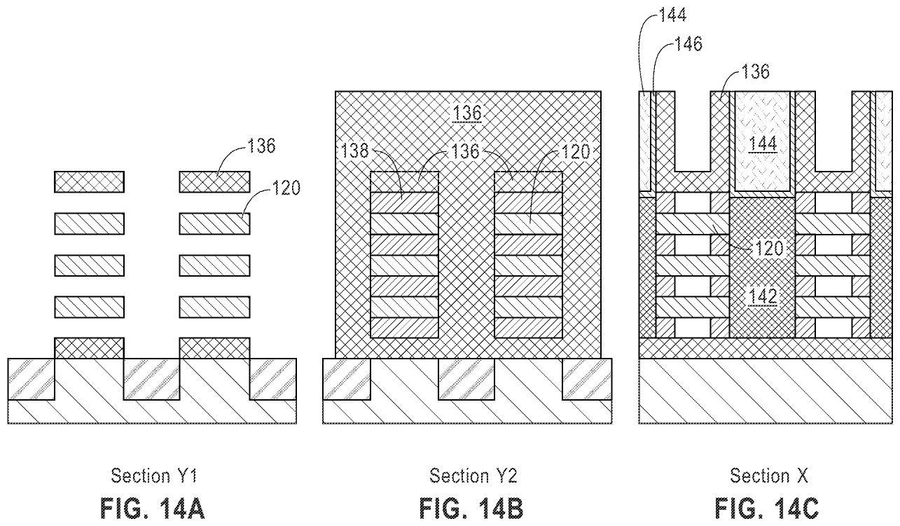

FIGS. 14A-14C show the formation after releasing (removing) the sacrificial suspension layers 124 from the fin stacks. As may be appreciated, by originally including two separate sacrificial suspension layers (122 and 124) on top of the top channel 120′, the process provides room for the TDI layer 135 and another layer below the TDI layer 135 that can be used to access all sides of the top channel 120′.

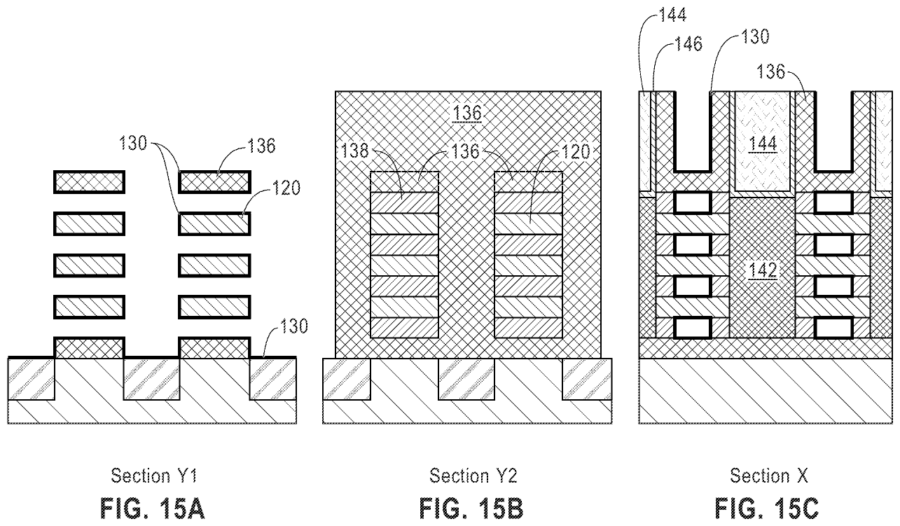

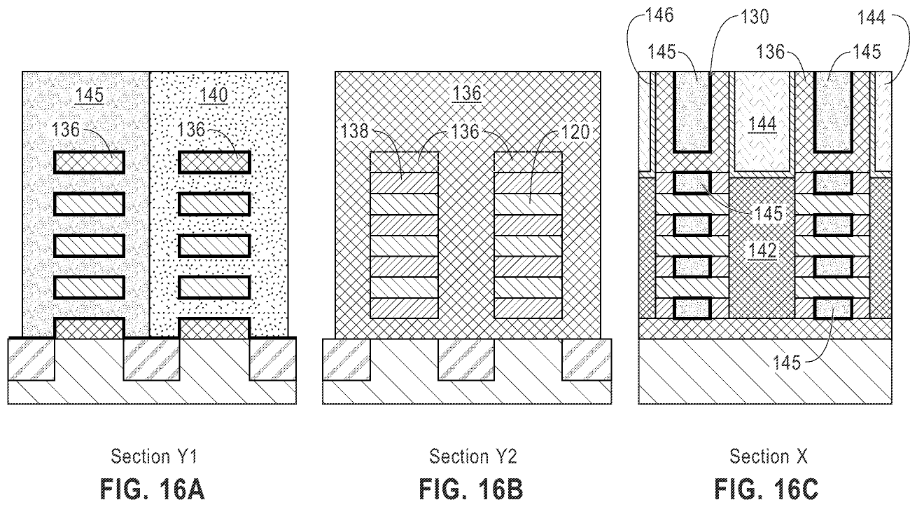

FIGS. 15A-15C show deposition of oxide layer 130 on to exposed surfaces of the semiconductor channels 120 and the spacer body 136. FIGS. 16A-16C deposition of work function metal films 140 and 145. As may be understood, the WFM film 140 may be configured for one type of FET and the WFM film 145 may be configured for a different type of FET (for example, nFET or pFET). In some embodiments, the device 100 may be complete at this stage after planarization or polishing (CMP process), which may be defined by the height of the ILD 144 (See FIG. 16C). In some embodiments, the CMP process may further lower the extended dummy gate height down into the level of the TDI layer 135. The end level of the CMP process will stop at the TDI layer 135 level. The formation will follow an integration along the advanced node technology. It should be further appreciated that since the metal height is self-aligned, there is no need to use a self-aligned cap. In addition, it should be understood that, for sake of illustration, while three semiconductor channels 120 were shown, by creating a self-aligned metal gate height, more room becomes available to use additional nanosheet channels if desired.

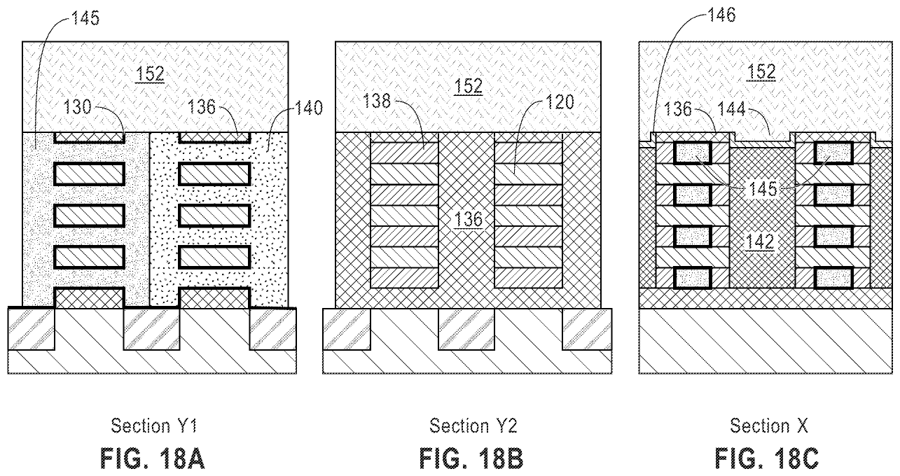

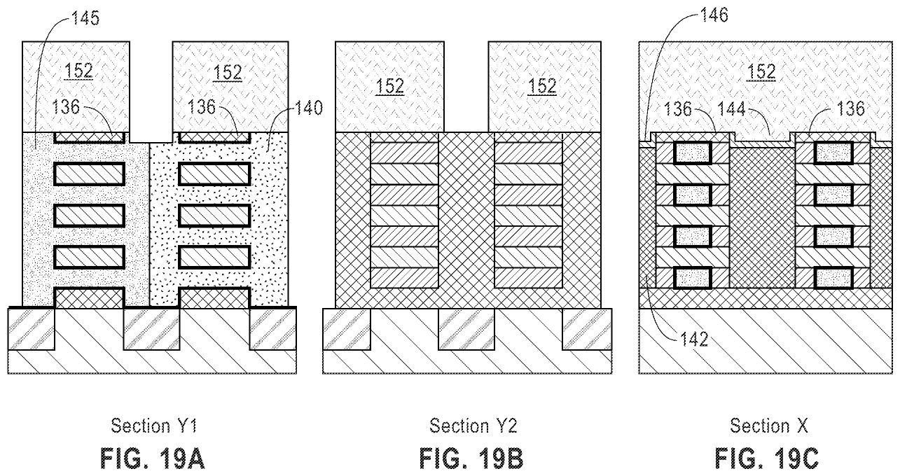

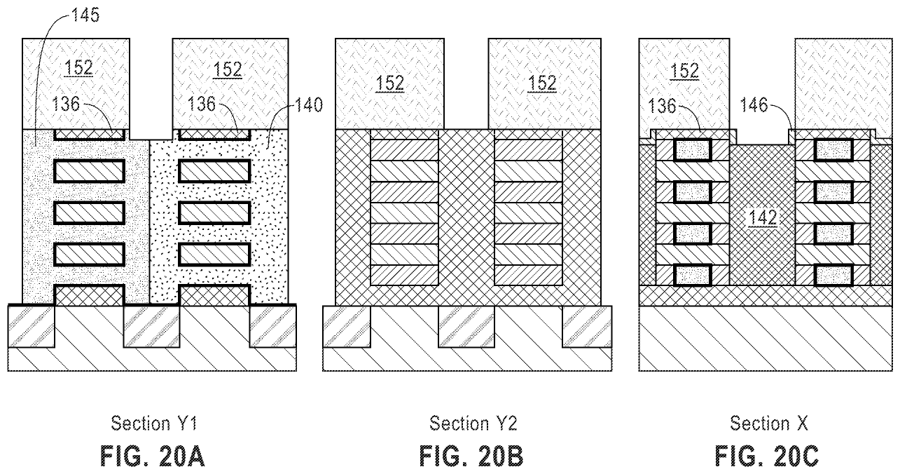

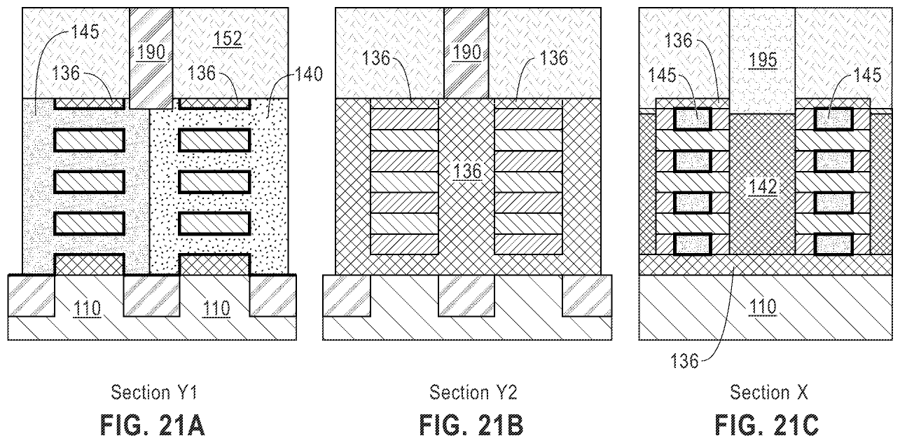

As shown in FIGS. 18A-18C, without the need for a self-aligned cap, the process may proceed to applying a middle of line (MOL) layer 152 over the device 100. FIGS. 19A-19C show the formation after an etch back process through the MOL layer 152 to contact the gates in the WFM films 140 and 145 (See especially FIG. 19A). FIGS. 20A-20C show the formation after an etch back process through the MOL layer 152 to contact the source-drain area in epitaxial layer 142 (See especially FIG. 20C). FIGS. 21A-21C show metal deposition to form the gate contact 190 and the source-drain contact 195. The formation in shown in FIGS. 21A-21C show one possible final structure according to embodiments.

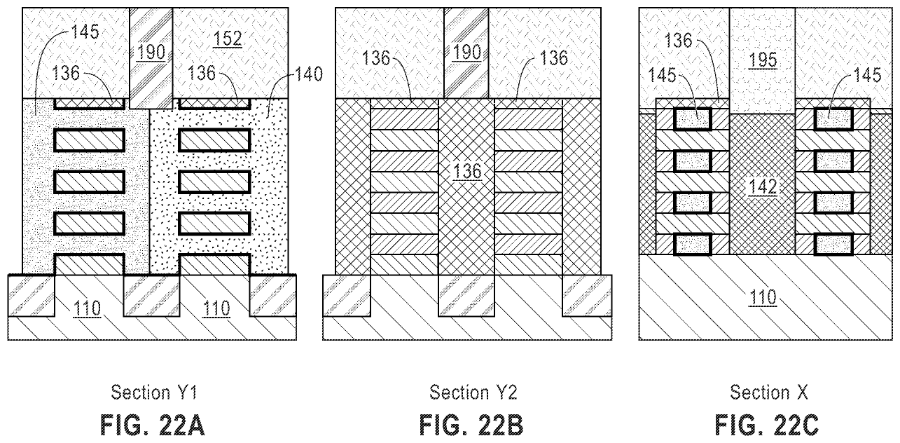

FIGS. 22A-22C show an embodiment similar to FIGS. 21A-21C except that the spacer body 136 does not extend down to a bottom dielectric isolation layer 175 as was formed in FIGS. 6A-6C. The embodiment shown in FIGS. 22A-22C is formed so that the fin stacks may be built directly on to the silicon substrate 110 (for example, by having a bottom semiconductor channel 120 being in contact with the substrate 110). In some embodiments, the substrate 110 and the layers of semiconductor channels 120 may share the same material. The bottom semiconductor channel 120 may appear to be continuous with the substrate 110 (as seen in FIGS. 22B and 22C) because of the commonality of material used. However, the embodiment still includes the TDI layer 135 above the top channel 120′.

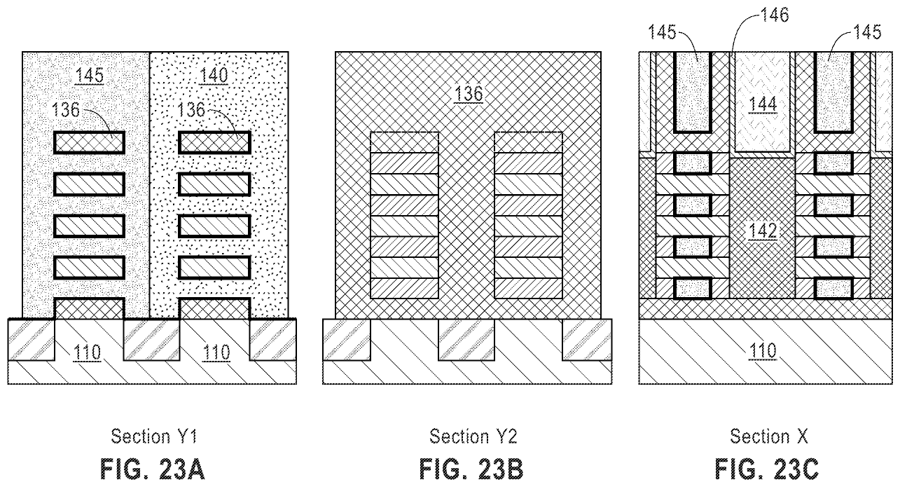

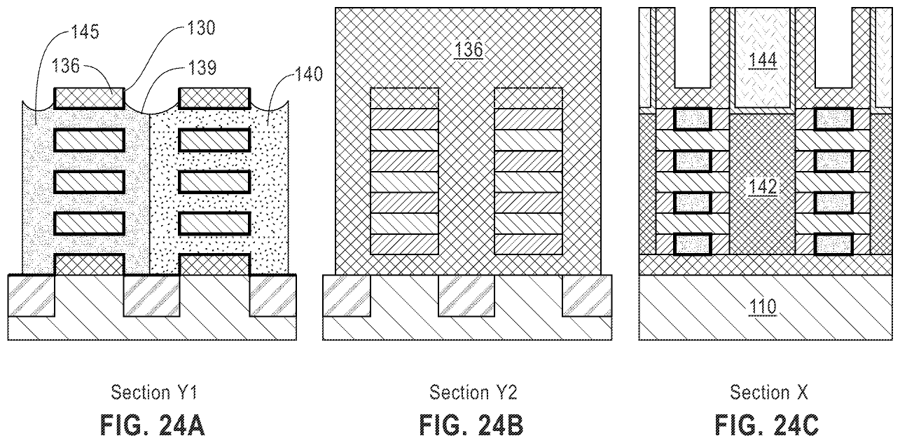

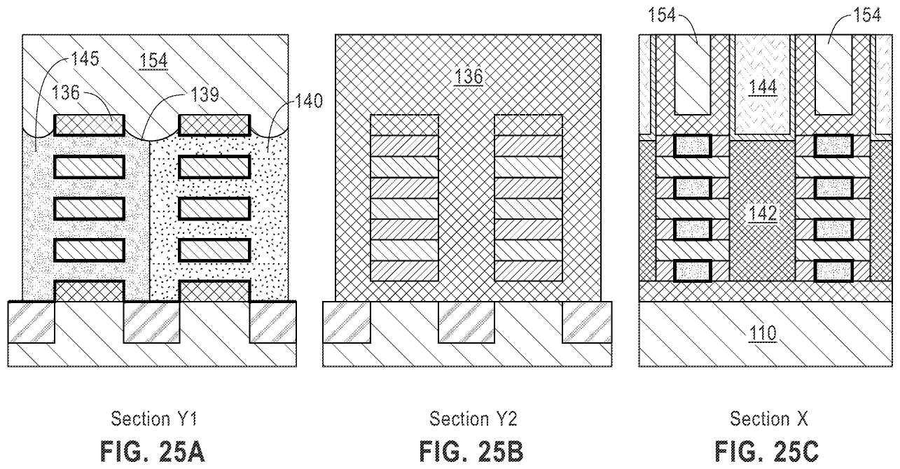

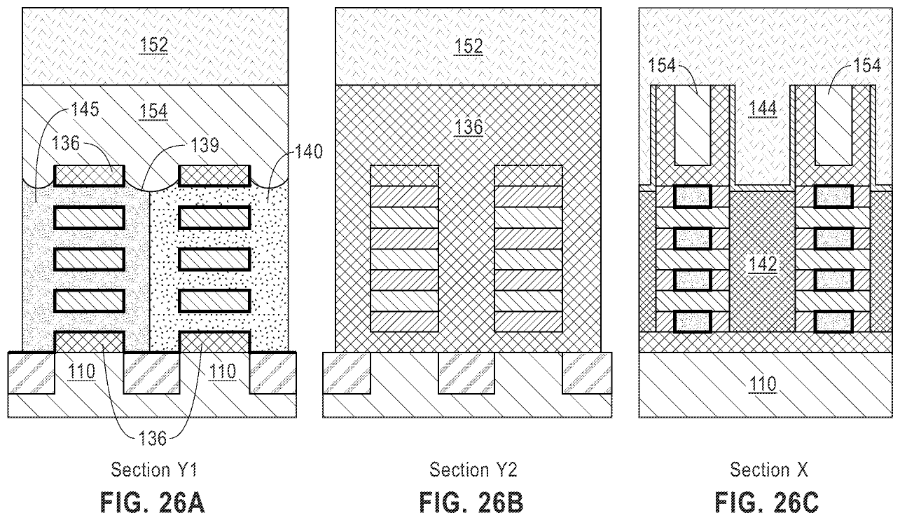

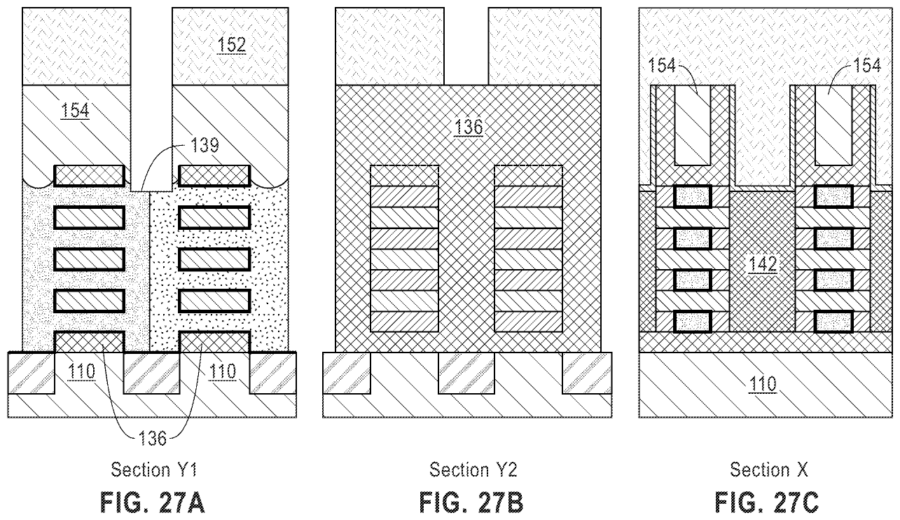

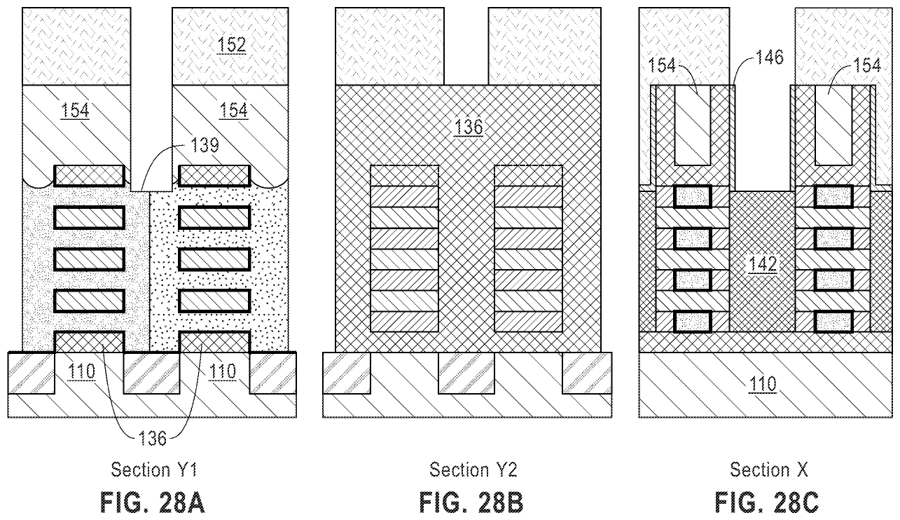

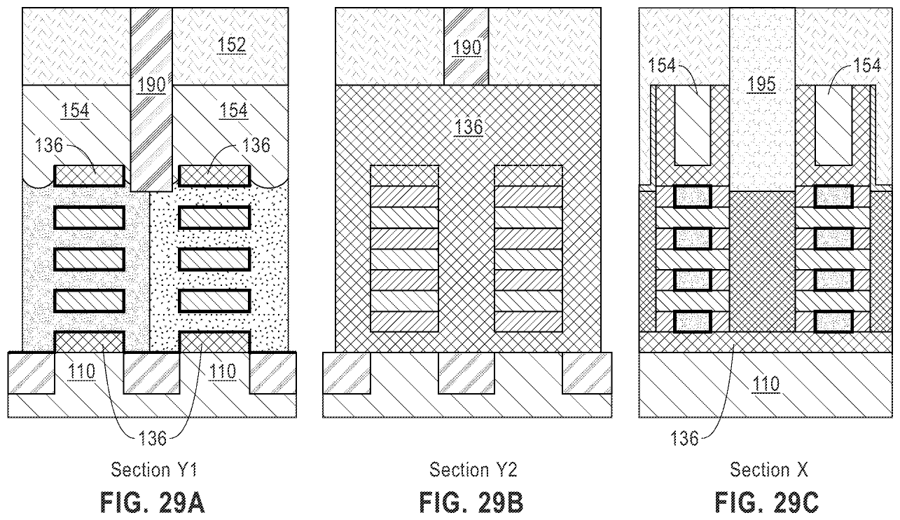

In FIGS. 23A-23C, the process flow begins from the formation shown in FIGS. 16A-16C. In FIGS. 24A-24C, the process includes recessing the gate metal in WFM films 140 and 145 using for example, a RIE process. Although a RIE process can be non-uniform in its etching, it may be appreciated that the TDI layer 135 level provides some buffer that allows a RIE to be used as long as the etching does not fall far (if at all) below the bottom of the TDI layer 135 level. As can be seen, the recess bottom wall 139 may be rounded in the WFM film areas 140; 145 but remains substantially distant from the boundaries of the top channels 120′. FIGS. 25A-25C show a formation that deposits a self-aligned cap over the TDI level and into the gate recesses. FIGS. 26A-26C show forming the middle of line interlevel dielectric layer 152. FIGS. 27A-27C show the formation after an etch back process through the MOL layer 152 and through the self-aligned cap 154 to contact the gates in the WFM films 140 and 145. FIGS. 28A-28C show the formation after an etch back process through the MOL layer 152 and through the self-aligned cap 154 to contact the source-drain area in epitaxial layer 142. FIGS. 29A-29C show metal deposition to form the gate contact 190 and the source-drain contact 195. The formation in shown in FIGS. 29A-29C show another possible final structure according to embodiments.

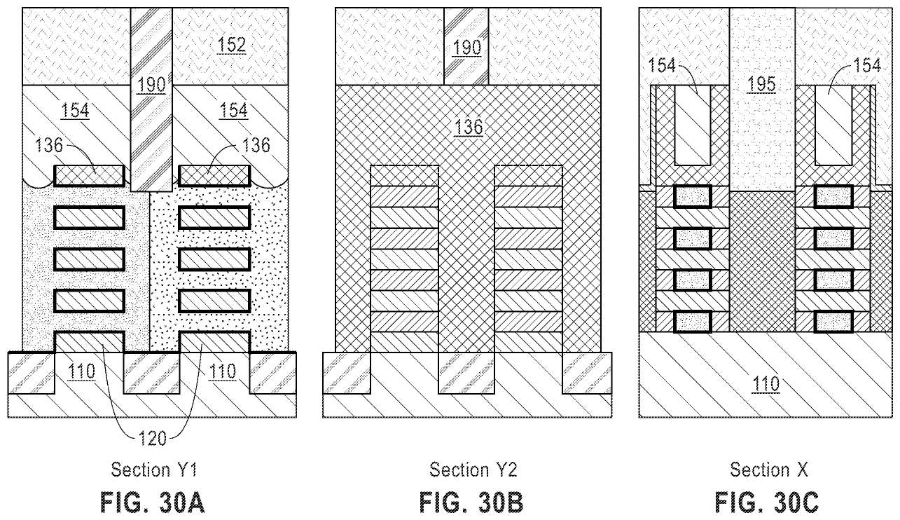

FIGS. 30A-30C show another possible final structure similar to the embodiment shown in FIGS. 29A-290C, except that the embodiment shown in FIGS. 30A-30C is formed so that the fin stacks may be built directly on to the silicon substrate 110 without the spacer body 136 extending down to a BDI layer 175 so that there is not spacer material under the fin stack and over the substrate 110. However, the embodiment still includes the TDI layer 135 above the top channel 120′.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
a stack of nanosheets supported by the substrate;
a plurality of semiconductor channels in the stack of nanosheets, wherein the plurality of semiconductor channels includes a top channel;
a gate body coupled to the top channel, including a layer of metal positioned on top of the top channel; and
a spacer body including a top dielectric layer positioned on top of the layer of metal, wherein a thickness of the layer of metal above the top channel is based on a distance from a bottom surface of the top dielectric layer to a top surface of the top channel.

2. The semiconductor device of claim 1, wherein a distance between the top channel and an underlying semiconductor channel is spaced by the distance from the bottom surface of the top dielectric layer to the top surface of the top channel.

3. The semiconductor device of claim 1, further comprising a bottom dielectric layer of the spacer body, positioned under a bottom channel of the plurality of semiconductor channels, and on top of the substrate.

4. The semiconductor device of claim 3, wherein the spacer body is a continuous body from the top dielectric layer to the bottom dielectric layer.

5. The semiconductor device of claim 1, further comprising a non-planar wall recessed into a top surface of the layer of metal, and disposed for receiving a metal contact.

6. The semiconductor device of claim 1, wherein the thickness of the layer of metal above the top channel is selected based on a targeted performance.

7. The semiconductor device of claim 1, further comprising a self-aligned cap positioned on top of the top dielectric layer and the gate body.

8. A semiconductor device, comprising:
a substrate;
a first fin field effect transistor (FET) on top of the substrate;
a first stack of nanosheets in the first fin FET;
a first top semiconductor channel in the first stack of nanosheets;
a first bottom semiconductor channel in the first stack of nanosheets;
a second fin FET on top of the substrate;
a second stack of nanosheets in the second fin FET;
a second top semiconductor channel in the second stack of nanosheets;
a second bottom semiconductor channel in the second stack of nanosheets;
a gate body coupled to the first top semiconductor channel, the second top semiconductor channel, the first bottom semiconductor channel, and the second bottom semiconductor channel, and including a layer of metal positioned on top of the first top semiconductor channel and on top of the second top semiconductor channel; and
a spacer body including a top dielectric layer positioned on top of the layer of metal, wherein a thickness of the layer of metal above the first top semiconductor channel is based on a distance from a bottom surface of the top dielectric layer to a top surface of either the first top semiconductor channel or the second top semiconductor channel.

9. The semiconductor device of claim 8, wherein the thickness of the layer of metal is uniform across the first fin FET and the second fin FET.

10. The semiconductor device of claim 8, further comprising a layer of metal between the first top semiconductor channel and the first bottom semiconductor channel, wherein said layer of metal has a same thickness as the layer of metal above the first top semiconductor channel.

11. The semiconductor device of claim 8, further comprising a first gate type material for the first fin FET and a second gate type material for the second fin FET.

12. The semiconductor device of claim 8, further comprising a bottom dielectric layer of the spacer body, positioned under the first and second bottom semiconductor channels, and on top of the substrate:

13. The semiconductor device of claim 8, wherein the spacer body continuously surrounds the first and second stacks of nanosheets.

14. The semiconductor device of claim 8, wherein the first fin FET is a nFET and the second fin FET is a pFET.

15. The semiconductor device of claim 8, wherein the first fin FET includes at least three semiconductor channels.

16. A method of manufacturing a semiconductor device, comprising:
forming a stack of nanosheets on a substrate, including:
providing at least a first semiconductor channel and a second semiconductor channel, and at least a first sacrificial suspension layer on top of the first semiconductor channel;
providing a second sacrificial suspension layer between the first semiconductor channel and the second semiconductor channel; and
providing a third sacrificial suspension layer under the second semiconductor channel;
forming a dielectric dummy layer on top of the first sacrificial suspension layer;
removing the dielectric dummy layer to define an empty area on top of the first sacrificial suspension layer;
depositing a spacer dielectric into at least the empty area on top of the first sacrificial suspension layer;
forming a fin field effect transistor (FET) from the stack of nanosheets, wherein at least some of the spacer dielectric is positioned on top of the fin FET;
forming a source and a drain coupled to the fin FET;
removing the first, second, and third sacrificial suspension layers; and
depositing a gate metal in areas including, above the first semiconductor channel, in between the first semiconductor channel and the second semiconductor channel, and under the second semiconductor channel, wherein a thickness of the gate metal positioned on top of the first semiconductor channel is pre-defined.

17. The method of claim 16, further comprising:
forming the dielectric dummy layer under the third sacrificial suspension layer and on top of the substrate in addition to forming the dielectric dummy layer on top of the first sacrificial suspension layer; and
replacing the dielectric dummy layer under the third sacrificial suspension layer with some of the spacer dielectric.

18. The method of claim 17, further comprising forming the spacer dielectric as a continuous body from on top of the gate metal positioned on top of the first semiconductor channel to the substrate.

19. The method of claim 16, further comprising removing any material from a top of the fin FET down into a layer of the spacer dielectric positioned above the first semiconductor channel and excluding the gate metal above the first semiconductor channel.

20. The method of claim 16, further comprising forming a distance of the second semiconductor channel from the first semiconductor channel based on the thickness of the gate metal positioned on top of the first semiconductor channel.
